(19) United States
(12) Patent Application Publication
(10) Pub. No.: US 2026/0075899 A1
(43) Pub. Date: Mar. 12, 2026

(54) SEMICONDUCTOR DEVICE

(71) Applicant: Samsung Electronics Co., Ltd., Suwon-si (KR)

(72) Inventors: Dowon SONG, Suwon-si (KR); Seowoo NAM, Suwon-si (KR); Heonjong SHIN, Suwon-si (KR); June Young PARK, Suwon-si (KR)

(21) Appl. No.: 19/065,703

(22) Filed: Feb. 27, 2025

(30) Foreign Application Priority Data
Sep. 12, 2024 (KR) 10-2024-0124624

(51) Int. Cl. H10D 62/10; H01L 21/762; H10D 30/00; H10D 30/01; H10D 64/23; H10D 64/27

(52) U.S. Cl. CPC H10D 62/124; H10D 30/502; H10D 64/258; H10D 64/518; H10D 30/019; H10D 62/121; H10W 10/014; H10W 10/17

(57) ABSTRACT

A semiconductor device includes an active pattern including a plurality of channel patterns in a first region, a gate electrode surrounding the channel patterns, a doped bottom pattern including a first well having a first conductivity type and a second well region at the same level as the first well region and having a second conductivity type in a second region, a device isolation layer between the active pattern and the doped bottom pattern, a first doped region in the first well region having a dopant concentration of the first conductivity type larger than that within the first well region, and a second doped region in the second well region having a dopant concentration of the second conductivity type larger than that within the second well region, wherein the first doped region and the second doped region are positioned higher than a bottom surface of the device isolation layer.

### CROSS-REFERENCE TO RELATED APPLICATION

This application claims priority to Korean Patent Application No. 10-2024-0124624, filed in the Korean Intellectual Property Office on Sep. 12, 2024, the entire contents of which are hereby incorporated by reference.

### BACKGROUND

### Field

The present disclosure relates to a semiconductor device.

### Description of Related Art

A semiconductor device may be a key part used to control or amplify an electric signal in an electronic apparatus, and various types of semiconductor devices may be manufactured. For example, a memory device may be mainly used to store and search for data, and a non-memory device may be used to control or amplify the electric signal. The semiconductor device as a core element of the electronic apparatus may play an important role in various fields such as computers, communication equipment, and consumer electronic products.

With the development of industry, demands for the performance and function of the electronic apparatus have been increased, and thus the high performance characteristics of the semiconductor device are needed. To meet the requirements, the integration of the semiconductor device has been increased. Various methods for forming a semiconductor device with excellent performance and improved integration have been studied.

### SUMMARY

To solve one or more problems (e.g., the problems described above and/or other problems not explicitly described herein), the present disclosure provides a semiconductor device with improved electrical characteristics and reliability.

To solve one or more problems (e.g., the problems described above and/or other problems not explicitly described herein), the present disclosure also provides a semiconductor device with improved design degree of freedom and process degree of freedom.

According to some example embodiments of the present disclosure for solving the above technical problems, a semiconductor device may include an active pattern including a plurality of channel patterns stacked to be spaced apart from each other in a first direction in a first region, a gate electrode surrounding the plurality of channel patterns, a doped bottom pattern including a first well having a first conductivity type and a second well region at the same level as the first well region and having a second conductivity type in a second region, a device isolation layer between the active pattern and the doped bottom pattern in a second direction intersecting with the first direction, a first doped region formed within the first well region and having a dopant concentration of the first conductivity type larger than a dopant concentration of the first conductivity type within the first well region, and a second doped region formed within the second well region and having a dopant concentration of the second conductivity type larger than a dopant concentration of the second conductivity type within the second well region, wherein a bottom surface of the device isolation layer is positioned at a level corresponding to a bottom surface of the doped bottom pattern, and the first doped region and the second doped region are positioned at a level higher than the bottom surface of the device isolation layer, respectively.

According to some example embodiments of the present disclosure for solving the above technical problems, a semiconductor device may include a lower insulating layer in a first region and a lower blocking layer in a second region, an active pattern including a plurality of channel patterns stacked to be spaced apart from each other in a first direction on the lower insulating layer, a gate electrode surrounding the plurality of channel patterns, a source/drain pattern in one sides of the plurality of channel patterns, a doped bottom pattern including a first well region and a second well region positioned side by side in a second direction intersecting with the first direction on the lower blocking layer, a first doped region formed in the first well region, and a second doped region formed in the second well region, wherein a bottom surface of the lower blocking layer is coplanar with a bottom surface of the lower insulating layer.

According to some example embodiments of the present disclosure for solving the above technical problems, a semiconductor device may include a lower insulating layer in a first region, and a lower blocking layer in a second region, an active pattern including a plurality of channel patterns stacked to be spaced apart from each other in a first direction on the lower insulating layer, a gate electrode surrounding the plurality of channel patterns, a source/drain pattern in one sides of the plurality of channel patterns, a doped bottom pattern including a first well region and a second well region which overlap in a second direction intersecting with the first direction on the lower blocking layer, a device isolation layer between the active pattern and the doped bottom pattern in the second direction, a first doped region formed in an upper side of the first well region, a second doped region formed in an upper side of the second well region, and positioned at a level corresponding to the first doped region, a first upper contact extending in the first direction on the first doped region, a second upper contact extending in the first direction on the second doped region, an upper wire at a level higher than the active pattern and the doped bottom pattern, and a lower wire at a level lower than the lower insulating layer and the lower blocking layer, a lower source/drain contact positioned on the source/drain pattern through the lower insulating layer, and electrically connecting the source/drain pattern and the lower wire, and a conductive post extending in the first direction and connecting between the upper wire and the lower wire.

According to some example embodiments of the present disclosure, the electrical characteristics and reliability of the semiconductor device may be improved.

According to some example embodiments of the present disclosure, the design degree of freedom and process degree of freedom in the semiconductor device may be improved.

### BRIEF DESCRIPTION OF THE DRAWINGS

FIG. 1 is a cross-sectional view illustrating a semiconductor device according to some example embodiments of the present disclosure.

FIGS. 2 to 19 are cross-sectional views illustrating intermediate stages, provided to explain a method for manufacturing a semiconductor device according to some example embodiments.

FIG. 20 is a cross-sectional view illustrating a semiconductor device according to some example embodiments of the present disclosure.

FIG. 21 is a cross-sectional view illustrating a semiconductor device according to some example embodiments of the present disclosure.

FIG. 22 is a cross-sectional view illustrating a semiconductor device according to some example embodiments of the present disclosure.

FIG. 23 is a cross-sectional view illustrating a semiconductor device according to some example embodiments of the present disclosure.

FIG. 24 is a cross-sectional view illustrating a semiconductor device according to some example embodiments of the present disclosure.

### DETAILED DESCRIPTION

Hereinafter, a semiconductor device according to some example embodiments of the present disclosure will be described in detail with reference to the drawings.

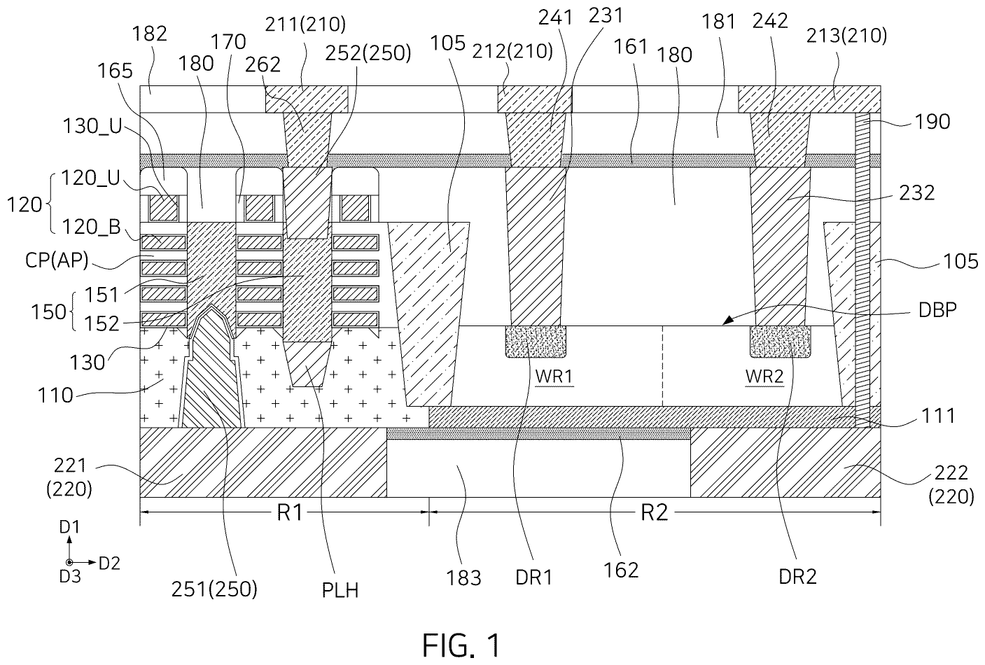

FIG. 1 is a cross-sectional view illustrating a semiconductor device according to some example embodiments of the present disclosure.

Referring to FIG. 1, the semiconductor device according to some example embodiments may include a first element disposed in a first region R1 and a second element disposed in a second region R2. The first element and the second element may include active elements different from each other. For example, the first element may be a transistor and the second element may be a diode. However, example embodiments are not limited thereto, and the first element may be disposed in the second region R2, and the second element may be disposed in the first region R1. In some example embodiments, the second element may include a passive element such as an inductor and a capacitor.

The semiconductor device according to some example embodiments may include a metal oxide semiconductor field effect transistor (MOSFET). For example, the semiconductor device may include a three-dimensional (3D) multi stack semiconductor device called a gate-all-around FET (GAAFET) and a multi-bridge channel FET (MBCFET).

The semiconductor device may include a lower insulating layer 110, an active pattern AP, a doped bottom pattern DBP, a lower blocking layer 111, a device isolation layer 105, a gate electrode 120, a gate insulating layer 130, a source/drain pattern 150, a gate spacer 170, a first well region WR1, and a second well region WR2.

The lower insulating layer 110 may be disposed in the first region R1. The lower insulating layer 110 may include oxide, nitride, oxynitride, or a combination thereof. It is illustrated that the lower insulating layer 110 is a single layer, for clarity, but example embodiments are not limited thereto. For example, the lower insulating layer 110 may be formed of a plurality of layers.

The active pattern AP may be disposed on the lower insulating layer 110. The active pattern AP may include a plurality of channel patterns stacked in a first direction D1. The first direction D1 may be a direction perpendicular to a top surface of the lower insulating layer 110. The active pattern AP may be disposed to be spaced apart from an adjacent active pattern AP in a second direction D2. The active pattern AP may extend in a third direction D3. The first direction D1 may be a direction intersecting with the second direction D2. The third direction D3 may be a direction intersecting with the first direction D1 and the second direction D2. In some example embodiments, the active pattern AP may be disposed in a region in which a PMOS element is to be formed. In other example embodiments, the active pattern AP may be disposed in a region in which an NMOS element is to be formed.

The active pattern AP may be a multi-channel active pattern. The active pattern AP may include the plurality of channel patterns CP. The plurality of channel patterns CP may be disposed on the lower insulating layer 110. For example, the lower insulating layer 110 may be disposed at a level lower than the active pattern AP. The channel patterns CP may be spaced apart from each other in the first direction D1. The first direction D1 may be a thickness direction of the lower insulating layer 110. In some example embodiments, the channel patterns CP may have a nanosheet shape. Four channel patterns CP are illustrated in FIG. 1, but example embodiments are not limited thereto.

The channel pattern CP may include one of silicon (Si) which is an elemental semiconductor material, a group IV-IV compound semiconductor (for example, silicon germanium (SiGe)), and a group III-V compound semiconductor.

The gate electrode 120 may extend on the lower insulating layer 110 in the third direction D3. The gate electrode 120 may be intersected with the active pattern AP. The gate electrode 120 may be disposed on the lower insulating layer 110. The gate electrode 120 may be disposed to be spaced apart from an adjacent gate electrode 120 in the second direction D2. The gate electrode 120 may surround the plurality of channel patterns CP. The gate electrode 120 may surround four surfaces of the channel pattern CP. For example, the gate electrode 120 may surround a top surface, a bottom surface, and both side surfaces of the channel pattern CP. In this example, the top surface and the bottom surface of the channel pattern CP may refer to surfaces perpendicular to the first direction D1, and both side surfaces of the channel pattern CP may refer to surfaces perpendicular to the third direction D3.

The gate electrode 120 may include an upper gate electrode 120_U and lower gate electrodes 120_B. The lower gate electrodes 120_B may be disposed between the channel patterns CP adjacent to each other in the first direction D1. The lower gate electrodes 120_B may be disposed between the plurality of channel patterns CP and may be disposed between the lower insulating layer 110 and a lowermost channel pattern CP of the plurality of channels patterns CP. The upper gate electrode 120_U may be disposed on an uppermost channel pattern CP of the plurality of channel patterns CP.

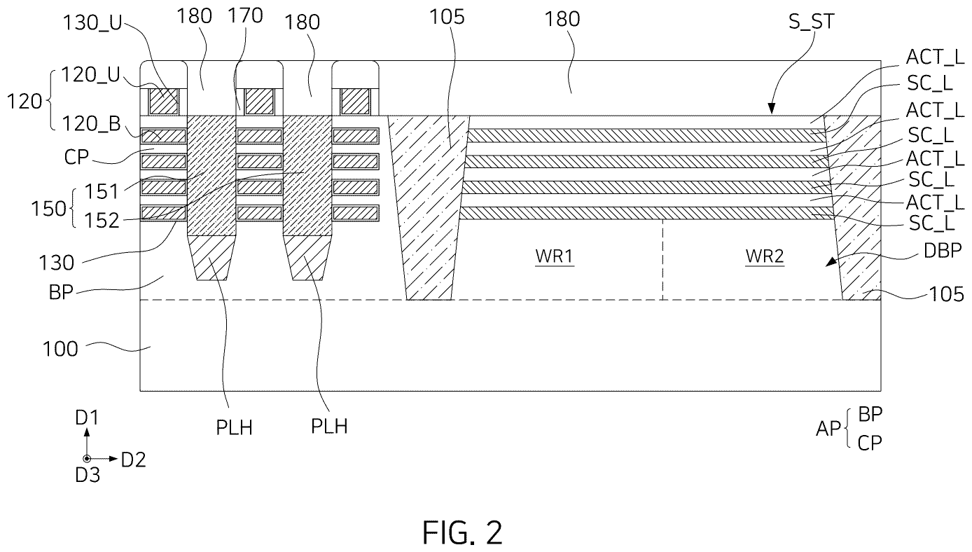

According to some example embodiments, the active pattern AP may include the plurality of channel patterns CP, and the gate electrode 120 may include a plurality of lower gate electrodes 120_B. For example, the number of lower gate electrodes 120_B may be in proportion to the number of channel patterns CP included in the active pattern AP. In this example, the number of lower gate electrodes 120_B may be the same as the number of channel patterns CP. As shown in FIG. 2, the number of the lower gate electrodes 120_B may be, for example, four which is the same as the number of channel patterns CP. However, example embodiments are not limited thereto.

The gate electrode 120 may include at least one of metal, metal alloy, conductive metal nitride, metal silicide, a doped semiconductor material, conductive metal oxide, and conductive metal oxynitride. For example, the gate electrode 120 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAlC-N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but example embodiments are not limited thereto. The conductive metal oxide and the conductive metal oxynitride may include oxidized forms of the above-described materials, but example embodiments are not limited thereto.

The top surface of the lower insulating layer 110 may be in contact with a lower surface of the gate insulating layer 130 disposed on the lowermost lower gate electrode 120_B. In some example embodiments, the top surface of the lower insulating layer 110 may have a facet structure. A portion of a substrate may be arranged on the top surface of the lower insulating layer 110.

The gate insulating layer 130 may be disposed between the gate electrode 120 and the plurality of channel patterns CP, between the gate electrode 120 and the lower insulating layer 110, and between the gate electrode 120 and the source/drain pattern 150. For example, the gate insulating layer 130 may be disposed between the upper gate electrode 120-U and the uppermost channel pattern CP of the plurality of channel patterns CP. The gate insulating layer 130 may be disposed between the lower gate electrodes 120_B and the channel patterns CP.

The gate spacer 170 may be disposed on a side surface of the upper gate electrode 120_U. For example, the gate spacer 170 may extend along the side surface of the upper gate electrode 120_U. The gate spacer 170 may not be disposed between the channel patterns CP adjacent in the first direction D1.

The gate spacer 170 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof. It is illustrated that the gate spacer 170 is a single layer, for clarity, but example embodiments are not limited thereto.

In some example embodiments, the gate insulating layer 130 may be disposed between the upper gate electrode 120_U and the channel pattern CP and may not be disposed on the gate spacer 170. For example, the gate insulating layer 130 may not be disposed between the gate spacer 170 and the upper gate electrode 120_U and between the gate spacer 170 and a gate capping pattern 165, but example embodiments are not limited thereto.

The gate capping pattern 165 may be disposed on the upper gate electrode 120_U and the gate spacer 170. The gate capping pattern 165 may cover a top surface of the upper gate electrode 120_U. The gate capping pattern 165 may overlap the upper gate electrode 120_U in the first direction D1. A top surface of the gate capping pattern 165 may be disposed in the same plane as a top surface of a first interlayer insulating layer 180, but example embodiments are not limited thereto. A width of the gate capping pattern 165 in the first direction D1 may be larger than a width of the upper gate electrode 120_U in the first direction D1.

In some example embodiments, the gate capping pattern 165 may be disposed between the gate spacers 170. For example, the width of the gate capping pattern 165 in the first direction D1 may correspond to the width of the upper gate electrode 120-U in the first direction D1.

The gate capping pattern 165 may include, for example, at least one of silicon nitride (SIN), silicon oxynitride (SiON), silicon carbonitride (SiCN), silicon oxycarbonitride (SiOCN), and a combination thereof. The gate capping pattern 165 may include a material having an etching selectivity to the first interlayer insulating layer 180.

The source/drain pattern 150 may be disposed on the lower insulating layer 110. The source/drain pattern 150 may be connected to the channel patterns CP. Some portions of a sidewall of the source/drain pattern 150 may be in contact with the channel patterns CP. Other portions of the sidewall of the source/drain pattern 150 may be in contact with the gate insulating layer 130. The source/drain pattern 150 may connect the channel patterns CP spaced apart in the first direction D1. The source/drain pattern 150 may be disposed between the channel patterns CP spaced apart in the second direction D2.

The source/drain pattern 150 may be disposed at least one side of the gate electrode 120. The source/drain pattern 150 may be disposed between the gate electrodes 120 adjacent in the second direction D2. For example, the source/drain pattern 150 may be disposed in both sides of the lower gate electrodes 120_B. The source/drain pattern 150 may be disposed in one side of the gate electrode 120 and may not be disposed in the other side of the gate electrode 120.

The source/drain pattern 150 may include a first source/drain pattern 151 and a second source/drain pattern 152. The first source/drain pattern 151 and the second source/drain pattern 152 may be spaced apart from each other in the second direction D2. Each of the first source/drain pattern 151 and the second source/drain pattern 152 may be disposed between the channel patterns CP spaced apart in the second direction D2 and between the lower gate electrodes 120_B spaced apart in the second direction D2.

The source/drain pattern 150 may be an epitaxial pattern formed through a selective epitaxial growth process using the active pattern AP or the substrate as a seed. The source/drain pattern 150 may serve as a source/drain of a transistor using the channel patterns CP as a channel region.

The source/drain pattern 150 may include a semiconductor material. The source/drain pattern 150 may include, for example, silicon (Si) or germanium (Ge) as an elemental semiconductor material. The source/drain pattern 150 may include, for example, a binary compound or a ternary compound which includes at least two or more of carbon (C), silicon (Si), germanium (Ge), and tin (Sn), or a compound in which a group IV element is doped in a binary compound or a ternary compound. For example, the source/drain pattern 150 may include silicon (Si), silicon-germanium (SiGe), germanium (Ge), silicon carbide (SiC), or the like, but example embodiments are not limited thereto.

The source/drain pattern 150 may include an impurity doped in a semiconductor material. The doped impurity may include at least one of boron (B), phosphorus (P), carbon (C), arsenic (As), antimony (Sb), bismuth (Bi), and oxygen (O), but example embodiments are not limited thereto.

It is illustrated that the source/drain pattern 150 is a single layer, for clarity, but example embodiments are not limited thereto. In some example embodiments, the source/drain pattern 150 may include a plurality of layers including different materials from each other. In other example embodiments, the source/drain pattern 150 may include a plurality of layers which include the same material as each other and have concentrations of constituent materials different from each other.

The first interlayer insulating layer 180 may be disposed on the source/drain pattern 150. The first interlayer insulating layer 180 may be disposed in one side of the upper gate electrode 120_U. The first interlayer insulating layer 180 may be disposed between the upper gate electrodes 120_U.

The first interlayer insulating layer 180 may include, for example, at least one of silicon oxide (SiO₂), silicon nitride (SiN), silicon oxynitride (SiON), and a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazene (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but example embodiments are not limited thereto.

A source/drain contact 250 may be disposed on the source/drain pattern 150. The source/drain contact 250 may pass through the first interlayer insulating layer 180 and a portion of the source/drain pattern 150. The source/drain contact 250 may be connected to the source/drain pattern 150. For example, a lower source/drain contact 251 may be disposed on the first source/drain pattern 151, and an upper source/drain contact 252 and a sacrificial contact pattern PLH may be disposed on the second source/drain pattern 152. However, example embodiments may be merely exemplary and the upper source/drain contact may be disposed on the first source/drain pattern 151, and the lower source/drain contact may be disposed on the second source/drain pattern 152. In some example embodiments, both the upper source/drain contact and the lower source/drain contact may be disposed on the first source/drain pattern 151 or the second source/drain pattern 152.

A metal-semiconductor compound layer, for example, a silicide layer may be interposed between the source/drain contact 250 and the source/drain pattern 150. The source/drain contact 250 may be electrically connected to the source/drain pattern 150 through the silicide layer. For example, the silicide layer may include at least one of titanium-silicide, tantalum silicide, tungsten-silicide, nickel-silicide, and cobalt-silicide.

The source/drain contact 250 may include a conductive material. For example, the source/drain contact 250 may include at least one of metal, metal nitride, metal carbonitride, a two-dimensional (2D) material, and a conductive semiconductor material. The source/drain contact 250 may include a barrier layer which surrounds the conductive material. The barrier layer may include a metal layer/a metal nitride layer. The metal layer may include at least one of Ti, Ta, W, Ni, Co, and Pt. The metal nitride layer may include at least one of titanium nitride (TiN), tantalum nitride (TaN), tungsten nitride (WN), nickel nitride (NiN), cobalt nitride (CON), and platinum nitride (PtN).

The lower blocking layer 111 may be disposed in the second region R2. The lower blocking layer 111 may be in contact with the lower insulating layer 110 in the second direction D2. A bottom surface of the lower insulating layer 110 may be coplanar with a bottom surface of the lower blocking layer 111.

The lower blocking layer 111 may include oxide, nitride, oxynitride, or a combination thereof. It is illustrated that the lower blocking layer 111 is a single layer, for clarity, but example embodiments are not limited thereto. For example, the lower blocking layer 111 may be formed of a plurality of layers.

A doped bottom pattern DBP may be disposed on the lower blocking layer 111. For example, the lower blocking layer 111 may be disposed at a level lower than the doped bottom pattern DBP. The doped bottom pattern DBP may extend in the third direction D3. The doped bottom pattern DBP may be formed by etching a portion of the substrate, but example embodiments are not limited thereto. For example, the doped bottom pattern DBP may include an epitaxial layer grown from the substrate. The doped bottom pattern DBP may include Si or Ge as an elemental semiconductor material. The doped bottom pattern DBP may include a compound semiconductor. For example, the doped bottom pattern DBP may include a group IV-IV compound semiconductor or a group III-V compound semiconductor.

The group IV-IV compound semiconductor may be, for example, a binary compound or a ternary compound including at least two or more of C, Si, Ge, and Sn.

The group III-V compound semiconductor may be, for example, one of a binary compound, a ternary compound, and a quaternary compound which is formed by combining at least one of Al, Ga, and indium (In) as a group III element and at least one of P, As, and Sb as a group V element.

In some example embodiments, the doped bottom pattern DBP and the plurality of channel patterns CP may include Si. In other example embodiments, the doped bottom pattern DBP and the plurality of channel patterns CP may include SiGe. In further other example embodiments, the doped bottom pattern DBP may include Si, and the plurality of channel patterns CP may include SiGe.

The doped bottom pattern DBP may include the first well region WR1 and the second well region WR2. The first well region WR1 and the second well region WR2 may be positioned at the same level as each other. The first well region WR1 and the second well region WR2 may be disposed side by side in the second direction D2. The first well region WR1 and the second well region WR2 may be disposed to overlap in the second direction D2.

The first well region WR1 and the second well region WR2 may be regions in which the substrate are doped with impurities. The first well region WR1 and the second well region WR2 may be doped with the impurities having conductivity types opposite to each other. The first well region WR1 may be doped with an impurity having a first conductivity type, and the second well region WR2 may be doped with an impurity having a second conductivity type. For example, the first well region WR1 may be a region doped with a p-type impurity, and the second well region WR2 may be a region doped with a N-type impurity. When the well region is a N-type region, the well region may include a dopant such as P, As, and Sb, and when the well region is a p-type region, the well region may include a dopant such as B. The first well region WR1 and the second well region WR2 may form a PN junction to form a PN diode.

A first doped region DR1 may be formed in the first well region WR1, and a second doped region DR2 may be formed in the second well region WR2. The first doped region DR1 may be doped with an impurity having the same conductivity type as the first well region WR1. The first doped region DR1 may include the same dopant as the first well region WR1. The first doped region DR1 may be a region having an impurity concentration higher than that of the first well region WR1. The second doped region DR2 may be doped with an impurity having the same conductivity type as the second well region WR2. The second doped region DR2 may include the same dopant as the second well region WR2. The second doped region DR2 may be a region having an impurity concentration higher than that of the second well region WR2.

In some example embodiments of the present disclosure, the first doped region DR1 and the second doped region DR2 may be spaced apart from the lower blocking layer 111 in the first direction D1. The first doped region DR1 and the second doped region DR2 may be disposed in an upper side of the doped bottom pattern DBP. The first doped region DR1 may be disposed in an upper side of the first well region WR1, and the second doped region DR2 may be disposed in an upper side of the second well region WR2. A top surface of the first doped region DR1, a top surface of the second doped region DR2, a top surface of the first well region WR1, and a top surface of the second well region WR2 may be coplanar with each other.

The doped bottom pattern DBP may be separated from the lower insulating layer 110 by the device isolation layer 105. The device isolation layer 105 may be disposed on a side surface of the doped bottom pattern DBP. A top surface and a portion of a side surface of the device isolation layer 105 may be in contact with the first interlayer insulating layer 180. The device isolation layer 105 may be disposed in a boundary between the first region R1 and the second region R2. For example, the device isolation layer 105 may be disposed on a boundary between the lower insulating layer 110 and the lower blocking layer 111.

A top surface of the doped bottom pattern DBP may be positioned at a level corresponding to the top surface of the lower insulating layer 110. The top surface of the doped bottom pattern DBP may be positioned on the same level as a bottom surface of the gate insulating layer 130 disposed on the lowermost lower gate electrode 120_B.

The device isolation layer 105 may include, for example, oxide, nitride, oxynitride, or a combination thereof. It is illustrated that the device isolation layer 105 is a single layer, for clarity, but example embodiments are not limited thereto. For example, the device isolation layer 105 may be formed of a plurality of layers. The device isolation layer 105 may be an insulating layer for electrically isolating the active pattern from the doped bottom pattern and may include the same material as the lower insulating layer 110, and thus a boundary of the device isolation layer 105 and the lower insulating layer 110 may not be discriminated.

The top surface of the device isolation layer 105 may be positioned on the same level as a top surface of the upper most channel pattern CP. The side surface of the device isolation layer 105 may be in contact with side surfaces of the active patterns AP. A bottom surface of the device isolation layer 105 may be positioned at a level corresponding to a bottom surface of the doped bottom pattern DBP. The bottom surface of the device isolation layer 105 may be positioned on the same level as the bottom surface of the doped bottom pattern DBP. The bottom surface of the device isolation layer 105 may be coplanar with the bottom surface of the doped bottom pattern DBP. The first doped region DR1 and the second doped region DR2 formed in the doped bottom pattern DBP may be positioned at a level higher than the bottom surface of the device isolation layer 105.

An upper etch stop layer 161 may be disposed on the first interlayer insulating layer 180. The upper etch stop layer 161 may extend along a profile of the top surface of the first interlayer insulating layer 180 and a profile of the top surface of the gate capping pattern 165.

The upper etch stop layer 161 may include a material having an etching selectivity to the first interlayer insulating layer 180. For example, the upper etch stop layer 161 may include at least one of SiN, SiO, SiON, SiOCN, SiBN, SiOBN, SiOC, and a combination thereof.

A second interlayer insulating layer 181 may be disposed on the upper etch stop layer 161. For example, the second interlayer insulating layer 181 may include at least one of SiO, SiN, SiON, and a low-k material. An upper wire insulating layer 182 may be disposed on the second interlayer insulating layer 181.

An upper wire 210 may be disposed within the upper wire insulating layer 182. The upper wire 210 may be disposed at a level higher than the active pattern AP and the doped bottom pattern DBP. The upper wire 210 may be electrically connected to at least one of the source/drain pattern 150, the first well region WR1, and the second well region WR2. At least one of the first doped region DR1 and the second doped region DR2 may be electrically connected to the upper wire 210.

An upper via 262 may be disposed on the upper source/drain contact 252. The source/drain pattern 150 may be electrically connected to the upper wire 210. The upper via 262 may pass through the upper etch stop layer 161 and the second interlayer insulating layer 181. The upper via 262 may electrically connect the source/drain pattern 150 and the upper wire 210. The upper via 262 may be electrically connected to a first upper wire 211. The first upper wire 211 may extend in the third direction D3. A top surface of the upper via 262 may be in contact with a bottom surface of the first upper wire 211, and a bottom surface of the upper via 262 may be in contact with a top surface of the upper source/drain contact 252.

Upper contacts 231 and 232 may extend in the first direction D1. A first upper contact 231 may be disposed on the first doped region DR1 disposed in the upper side of the first well region WR1. A second upper contact 232 may be disposed on the second doped region DR2 disposed in the upper side of the second well region WR2. The first upper contact 231 and the second upper contact 232 may extend in the first direction D1, respectively.

A bottom surface of the first upper contact 231 may be in contact with the top surface of the first doped region DR1, and a bottom surface of the second upper contact 232 may be in contact with the top surface of the second doped region DR2. In some example embodiments, a silicide layer may be disposed between the first upper contact 231 and the first doped region DR1, and a silicide layer may be disposed between the second upper contact 232 and the second doped region DR2. The bottom surfaces of the upper contacts 231 and 232 may be positioned at a level corresponding to a bottom surface of the gate electrode 120. For example, the bottom surfaces of the upper contact 231 and 232 may be positioned at a level corresponding to a bottom surface of the lowermost lower gate electrode of the lower gate electrodes 120_B. In another example, the bottom surfaces of the upper contacts 231 and 232 may be positioned at the same level as the bottom surface of the gate insulating layer 130 disposed on the lowermost lower gate electrode 120_B of the lower gate electrodes 120_B.

Top surfaces of the upper contacts 231 and 232 may be coplanar with the top surface of the upper source/drain contact 252, respectively. The first upper contact 231 and the second upper contact 232 may be disposed on the top surface of the doped bottom pattern DBP, respectively, and thus a length of each of the first upper contact 231 and the second upper contact 232 in the first direction D1 may be larger than that of the upper source/drain contact 252 in the first direction D1, which is disposed on the second upper source/drain pattern 152.

Upper vias 241 and 242 may be disposed on the first upper contact 231 and the second upper contact 232, respectively. The upper vias 241 and 242 may electrically connect the upper contacts 231 and 231 and the upper wire 210, respectively. The upper vials 241 and 242 may pass through the upper etch stop layer 161 and the second interlayer insulating layer 181. The upper vials 241 and 242 may electrically connect the second well region WR2 and the upper wire 210. For example, the first well region WR1 may be electrically connected to a second upper wire 212, and the second well region WR2 may be electrically connected to a third upper wire 213. However, the connection structure may be merely exemplary, and the other connection structures may be provided.

A lower wire 220 may be disposed on the bottom surfaces of the lower insulating layer 110 and the lower blocking layer 111. For example, the lower wire 220 may be disposed at a level lower than the lower insulating layer 110 and the lower blocking layer 111. At least one of the first doped region DR1 and the second doped region DR2 may be electrically connected to the lower wire 220.

The lower wire 220 may include a first power line 221 and a second power line 222. For example, the first power line 221 and the second power line 222 may extend in the third direction D3, respectively. A lower etch stop layer 162 and a lower wire insulating layer 183 may be disposed between the first power line 221 and the second power line 222. The lower wire insulating layer 183 may be disposed on a bottom surface of the lower etch stop layer 162. The lower etch stop layer 162 may be disposed on a boundary between the lower insulating layer 110 and the lower blocking layer 111. The lower etch stop layer 162 may be disposed over the first region R1 and the second region R2.

The lower etch stop layer 162 may be configured of the same material as the upper etch stop layer 161. The lower wire insulating layer 183 may be configured of the same material as the first interlayer insulating layer 180.

The lower source/drain contact 251 may be disposed on a top surface of the first power line 221. The first source/drain pattern 151 may be electrically connected to the first power line 221. The lower source/drain contact 251 may be disposed on the top surface of the first power line 221 so that power may be supplied to the first source/drain pattern 151 from the first power line 221.

In some example embodiments, a conductive post 190 may be disposed on a top surface of the second power line 222. The conductive post 190 may electrically connect the upper wire 210 and the lower wire 220. The conductive post 190 may connect between the upper wire 210 and the lower wire 220. The conductive post 190 may electrically connect the second power line 222 and the third upper wire 213. The conductive post 190 may extend in the first direction D1. The conductive post 190 may supply power from the second power line 222 to the second well region WR2 through the third upper wire 213. The first doped region DR1 and the second doped region DR2 may be electrically connected to the second power line 222 through the conductive post 190. The conductive post 190 may have a length larger than those of the first upper contact 231 and the second upper contact 232 in the first direction D1. The conductive post 190 may pass through the second interlayer insulating layer 181, the upper etch stop layer 161, the first interlayer insulating layer 180, the device isolation layer 105, and the lower blocking layer 111 in the first direction D1. It is illustrated in FIG. 1 that the conductive post 190 is a single layer, but the structure of the conductive post 190 may be merely exemplary. In other example embodiments, the conductive post 190 may have a structure that a plurality of conductive layers are stacked.

The conductive post 190 may include, for example, at least one of W, Mo, Co, Cu, Al, Ti, Ta, and Ti/TiN, or a combination thereof.

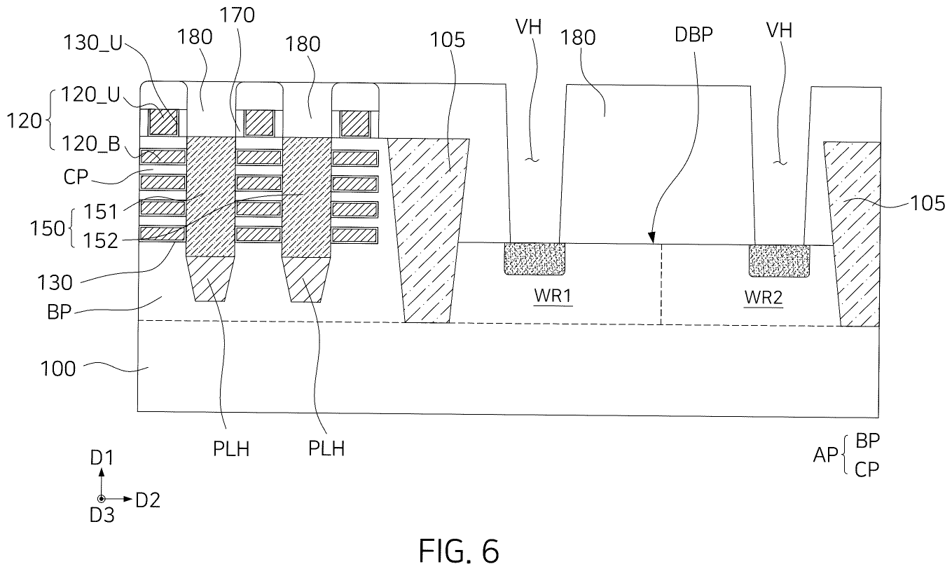

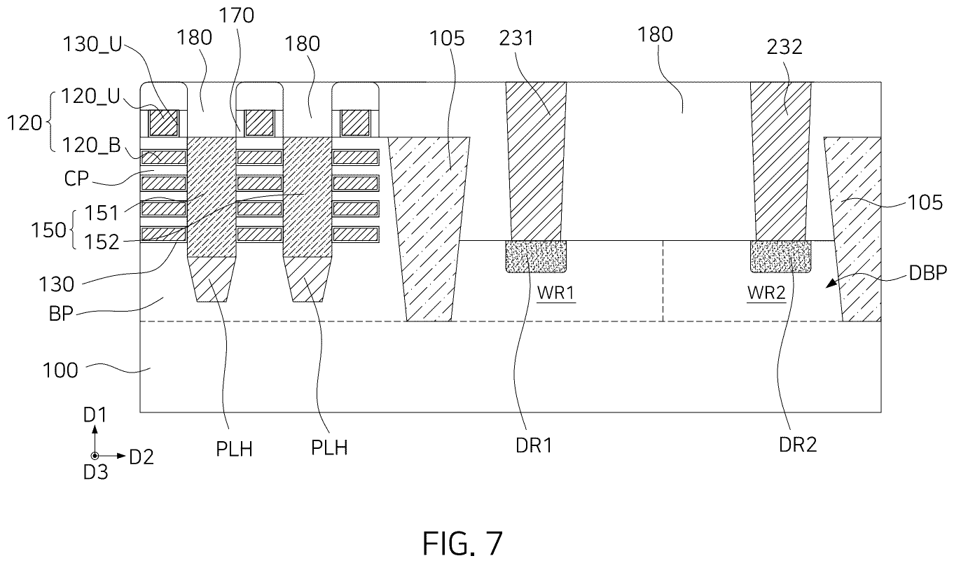

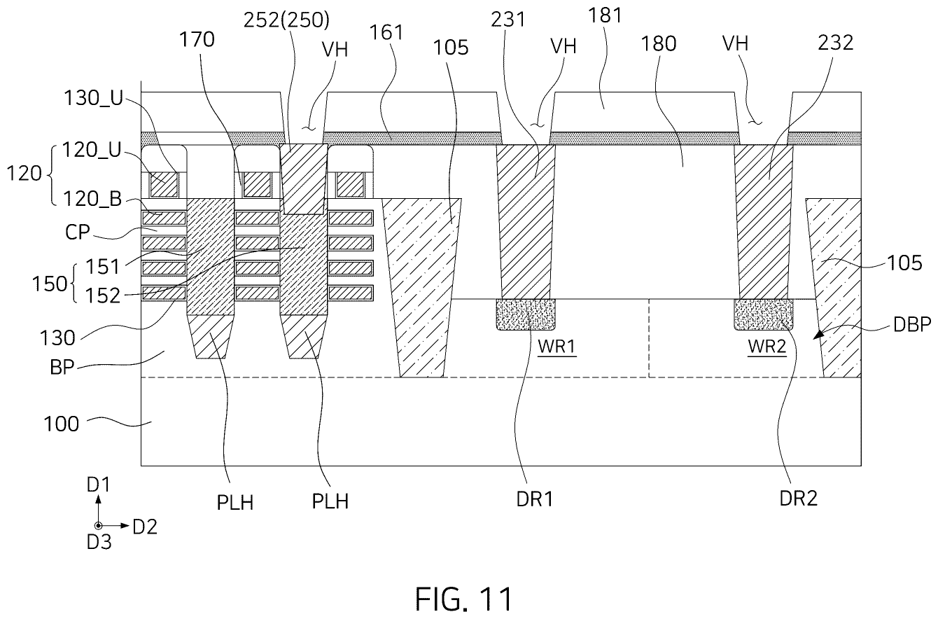

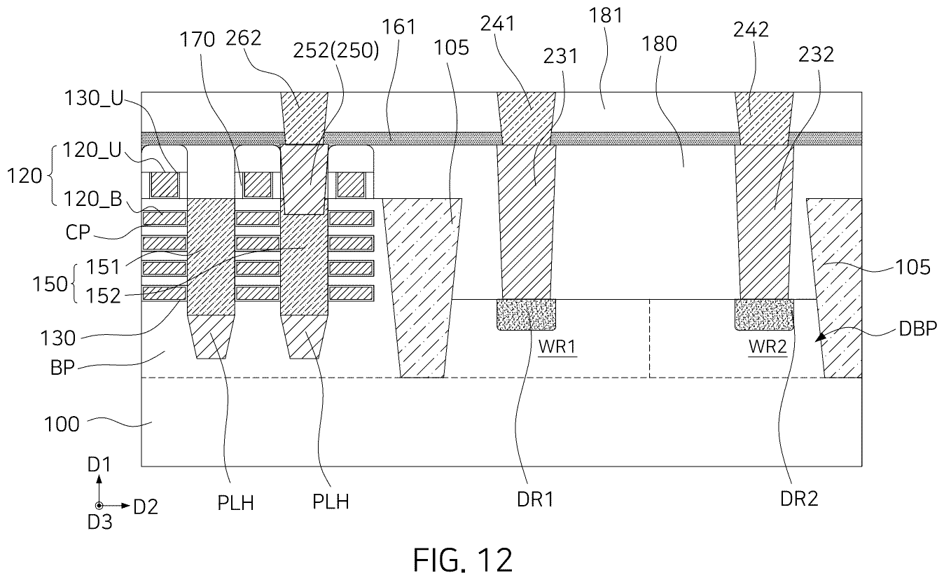

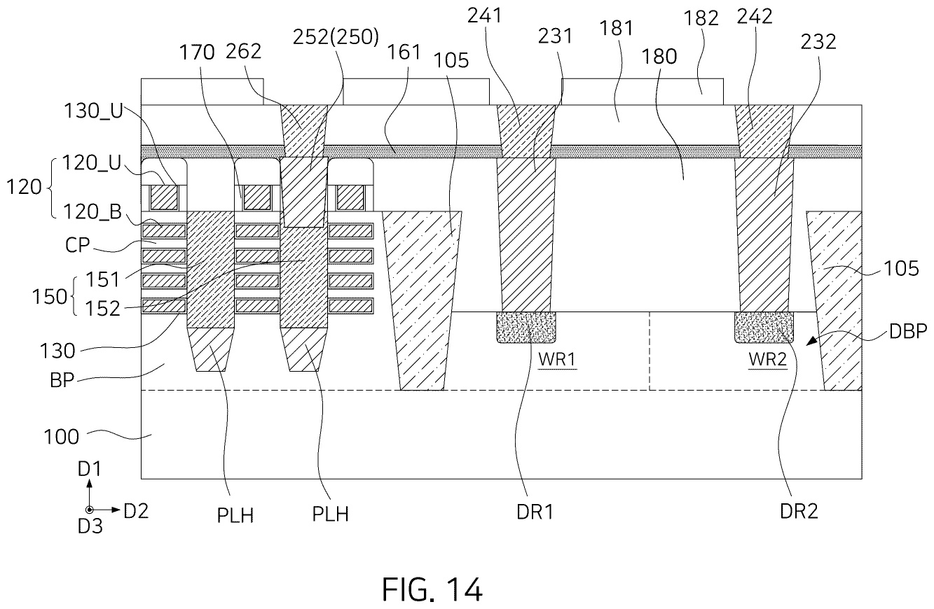

FIGS. 2 to 19 are diagrams illustrating intermediate stages, provided to explain a method for manufacturing a semiconductor device according to some example embodiments.

Referring to FIG. 2, the method for manufacturing a semiconductor device according to some example embodiments may include forming the first element including a bottom pattern BP, the device isolation layer 105, the doped bottom pattern DBP, a stack structure S_ST, the first interlayer insulating layer 180, and the like on a substrate 100.

The stack structure S-ST may be formed by alternately stacking a sacrificial semiconductor layer SC_L and an active semiconductor layer ACT_L on the substrate 100. The substrate 100 may be a silicon substrate. The substrate 100 may include another material, for example, silicon germanium (SiGe), silicon germanium on insulator (SGOI), indium antimonide (InSb), lead tellurium (PbTe), indium arsenide (InAs), indium phosphide (InP), gallium arsenide (GaAs) or gallium antimonide (GaSb), but example embodiments are not limited thereto.

The stack structure S-ST may include the sacrificial semiconductor layers SC L and the active semiconductor layers ACT_L alternately stacked. The sacrificial semiconductor layer SC_L may be disposed in a lowermost layer of the stack structure S ST. The active semiconductor layer ACT_L may be disposed in an uppermost layer of the stack structure S_ST. The active semiconductor layer ACT_L and the sacrificial semiconductor layer SC_L may be configured of materials having different etching selectivities from each other.

A mask pattern may be formed on the stack structure S_ST, and a portion of the stack structure S_ST may be patterned. For example, the portion of the stack structure S_ST may be selectively removed. The stack structure S_ST may be patterned to form a trench, the bottom pattern BP, and the doped bottom pattern DBP. The device isolation layer 105 may be formed within the trench. The trench may be filled with the device isolation layer 105. It is illustrated that the device isolation layer 105 is a single layer, but example embodiments are not limited thereto.

The doped bottom pattern DBP may be doped with an impurity. A portion of the doped bottom pattern DBP may be doped with an impurity having a first conductivity type to form the first well WR1, and the remaining portion of the doped bottom pattern DBP may be doped with an impurity having a second conductivity type to form the second well region WR2. The first well region WR1 and the second well region WR2 may be formed on the same level as each other. The first well region WR1 and the second well region WR2 may overlap in the second direction D2.

On the basis of the device isolation layer 105, a first region and a second region may be separated. A mask may be disposed in the second region, and then the first element may be formed in the first region. The first interlayer insulating layer 180 may be formed in the first region and the second region. For example, the first interlayer insulating layer 180 may be formed on the first element, the device isolation layer 105, and the stack structure S ST.

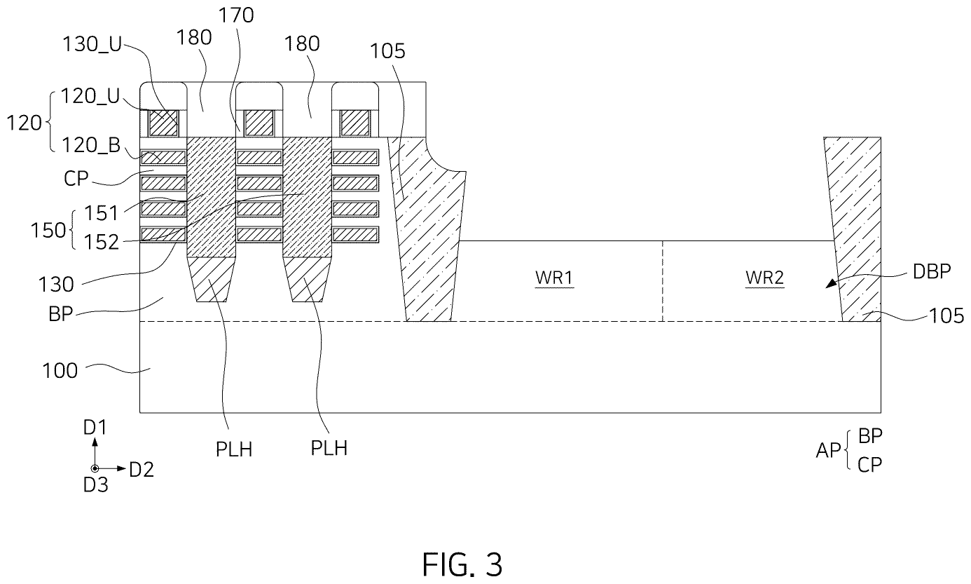

Referring to FIG. 3, a mask may be disposed on the first element, and then an etch process may be performed on the second region. Through the etch process, the first interlayer insulating layer 180 and the stack structure (see S_ST in FIG. 2) may be removed. As the stack structure is removed, the top surface of the doped bottom pattern DBP may be exposed. For example, the top surface of the first well region WR1 and the top surface of the second well region WR2 may be exposed in the first direction D1.

In some example embodiments, the device isolation layer 105 and the first interlayer insulating layer 180 may be isotropically etched through a wet etch process so that a portion of the device isolation layer 105 may be removed.

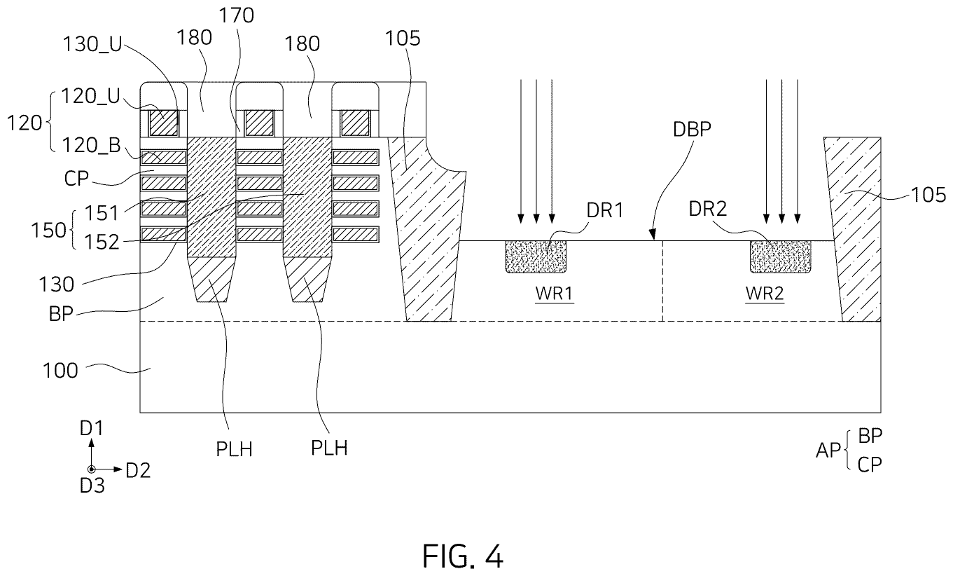

Referring to FIG. 4, respective ion implantation processes may be performed on the first well region WR1 and the second well region WR2. Impurities having concentrations larger than those of the first well region WR1 and the second well region WR2, respectively may be implanted into the first well region WR1 and the second well region WR2. A first conductivity type dopant may be implanted into the first well region WR1, and a second conductivity type dopant may be implanted into the second well region WR2. Accordingly, the first doped region DR1 may be formed in the upper side of the first well region WR1, and the second doped region DR2 may be formed in the upper side of the second well region WR2.

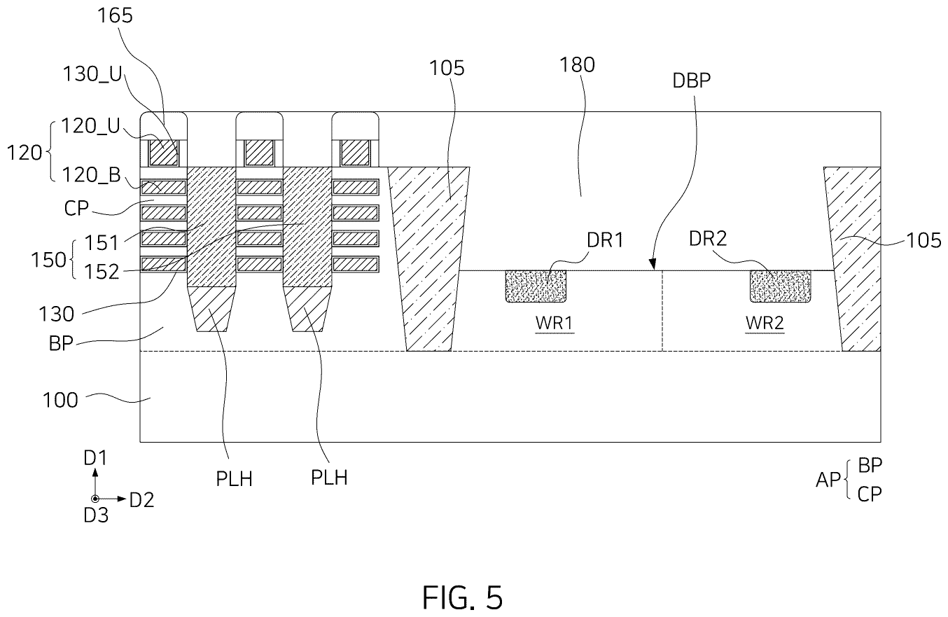

Referring to FIGS. 5 to 7, an insulating layer may be formed on the doped bottom pattern DBP. Accordingly, the device isolation layer 105 and the first interlayer insulating layer 180 on the doped bottom pattern DBP may be refilled.

A mask pattern may be formed on the first interlayer insulating layer 180. The mask pattern may expose a portion of the first interlayer insulating layer 180. For example, portions of the first interlayer insulating layer 180 corresponding to the first doped region DR1 and the second doped region DR2, respectively, may be exposed.

An etch process may be performed on the first interlayer insulating layer 180. A portion of the interlayer insulating layer 180 which is covered with the mask pattern may not be removed, and the portions of the interlayer insulating layer 180 which are exposed by the mask pattern may be removed. Via holes VH may be formed in the first interlayer insulating layer 180. In some example embodiments, the via holes VH may be formed to have cross-sectional areas which are reduced as the depths increase.

The first doped region DR1 and the second doped region DR2 may be exposed through the via holes VH, respectively. A metal material for forming the upper contacts 231 and 232 may be filled within the via holes VH. For example, the upper contacts 231 and 232 may include at least one of W, Mo, Co, Cu, Al, Ti, Ta, and Ti/TiN or a combination thereof. According to shapes of the via holes VH, the upper contacts 231 and 232 may be formed to have cross-sectional areas which are reduced toward lower ends of the via holes VH from upper ends thereof. However, the shapes of the via holes VH and the upper contacts 231 and 232 are not limited thereto, and the via holes VH and the upper contacts 231 and 232 may be formed to have uniform cross-sectional areas.

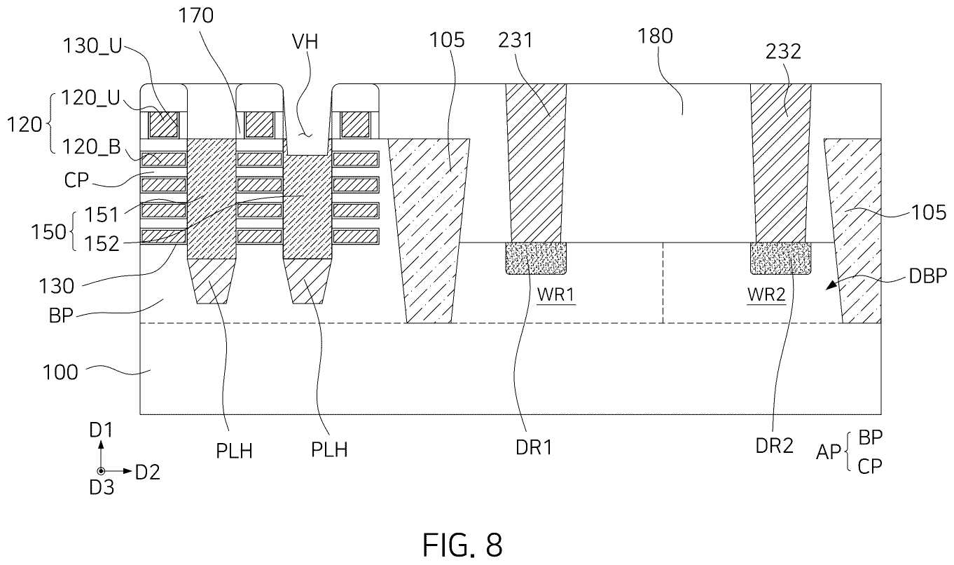

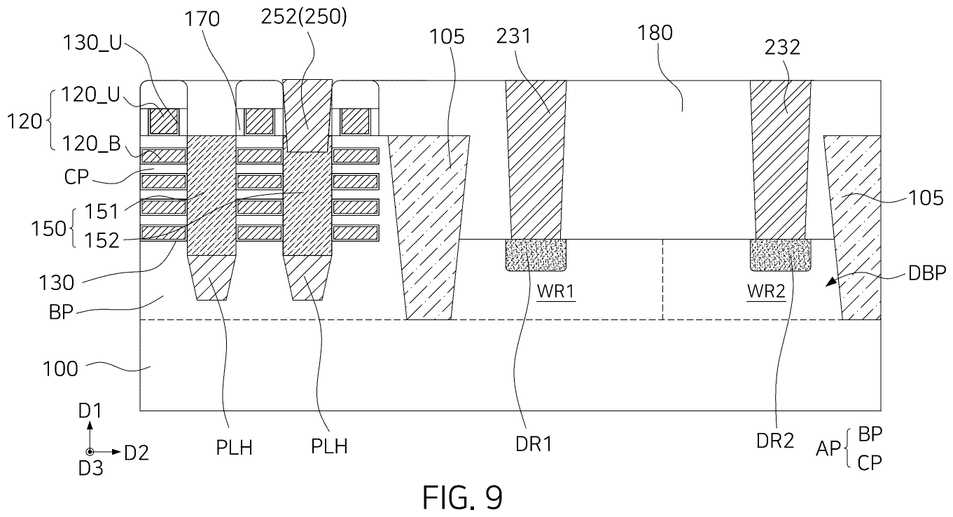

Referring to FIGS. 8 and 9, the source/drain contact 250 may be formed on the source/drain pattern 150. To form the source/drain contact 250, the mask pattern on the first element side may first be removed.

A mask pattern may be formed on the first element. The mask pattern may expose a portion of the interlayer insulating layer 180. For example, a portion of the first interlayer insulating layer 180 corresponding to the second source/drain pattern 152 may be exposed.

An etch process may be performed on the first interlayer insulating layer 180 exposed through the mask pattern. The portion of the interlayer insulating layer 180 may be removed through the etch process. In the etch process, a portion of the second source/drain pattern 152 may also be removed. A via hole VH may be formed in the first interlayer insulating layer 180 and the second source/drain pattern 152. In some example embodiments, the via hole VH may be formed to have a cross-sectional area which is reduced with a depth thereof.

The second source/drain pattern 152 may be exposed through the via hole VH. A metal material for forming the upper source/drain contact 252 may be filled within the via hole VH. For example, the upper source/drain contact 252 may include at least one of W, Mo, Co, Cu, Al, Ti, Ta, and Ti/TiN or a combination thereof.

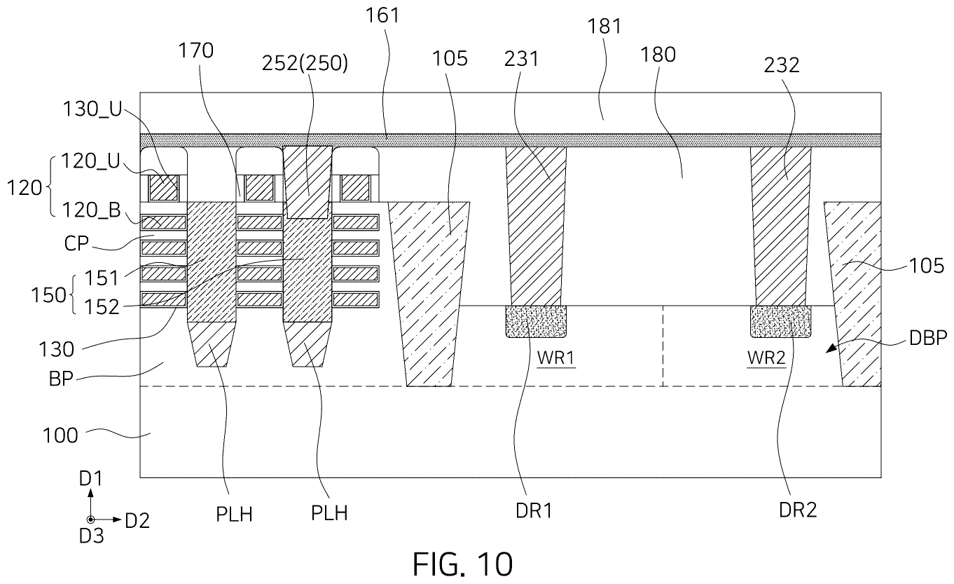

Referring to FIGS. 10 to 12, the upper etch stop layer 161 may be formed on the gate capping pattern 165, the first interlayer insulating layer 180, the upper contacts 231 and 232, and the upper source/drain contact 252. The upper etch stop layer 161 may be conformally formed. Subsequently, the second interlayer insulating layer 181 may be formed on the upper etch stop layer 161.

A mask pattern may be formed on the second interlayer insulating layer 181. The mask pattern may expose a portion of the second interlayer insulating layer 181. For example, portions of the second interlayer insulating layer 181 corresponding to the upper contacts 231 and 232 and the upper source/drain contact 252, respectively, may be exposed.

An etch process may be performed on the exposed second interlayer insulating layer 181 and the upper etch stop layer 161. Through the etch process, portions of the second interlayer insulating layer 181 and the upper etch stop layer 161 may be removed. Via holes VH may be formed in the second interlayer insulating layer 181 and the upper etch stop layer 161.

Top surfaces of the upper contacts 231 and 232 and a top surface of the upper source/drain contact 252 may be exposed through the via holes VH. First upper vias 241 and 242 and a second upper via 262 may be formed within the via holes VH. For example, the first upper vias 241 and 242 and the second upper via 262 may include at least one of W, Mo, Co, Cu, Al, Ti, Ta, and Ti/TiN or a combination thereof.

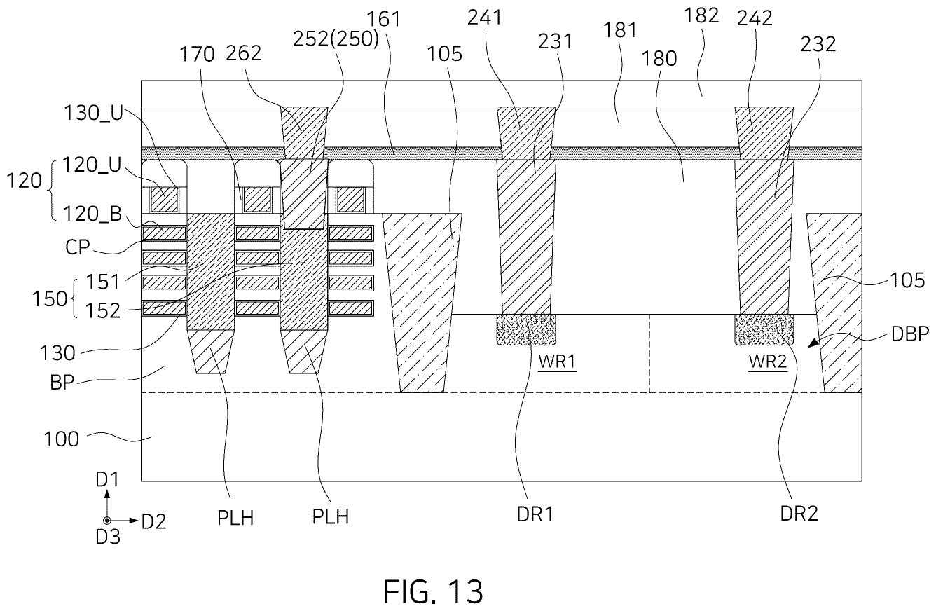

Referring to FIGS. 13 to 15, the upper wire insulating layer 182 may be formed on the second interlayer insulating layer 181. A mask pattern may be formed on the upper wire insulating layer 182. The mask pattern may expose a portion of the upper wire insulating layer 182. For example, portions of the upper wire insulating layer 182 corresponding to the first upper vias 241 and 242 and the second upper via 262, respectively, may be exposed.

An etch process may be performed on the upper wire insulating layer 182 exposed through the mask pattern. The portions of the upper wire insulating layer 182 may be removed through the etch process. The upper wires 210 may be formed in the portions of the upper wire insulating layer 182 which are removed through the etch process.

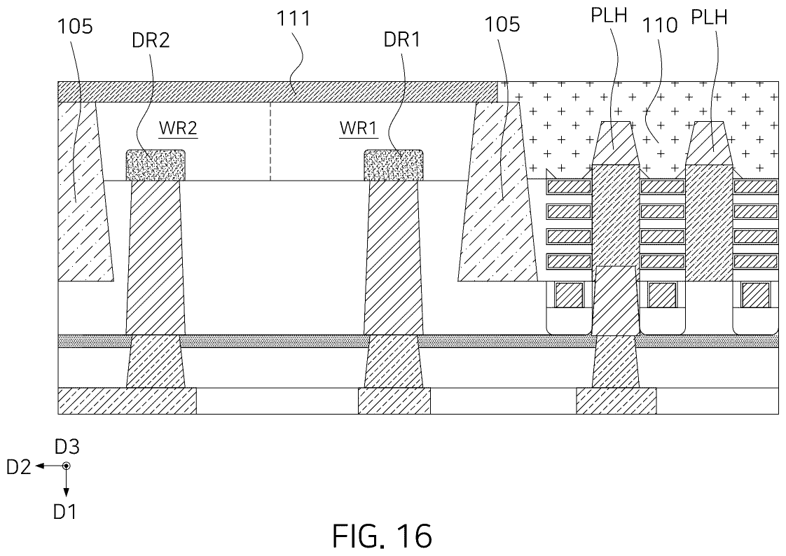

Referring to FIG. 16, the semiconductor device may be turned over so that the substrate faces upward, and then the substrate may be removed. After the substrate is removed, a planarization process may be performed. For example, the planarization process may be a chemical mechanical polishing (CMP) process.

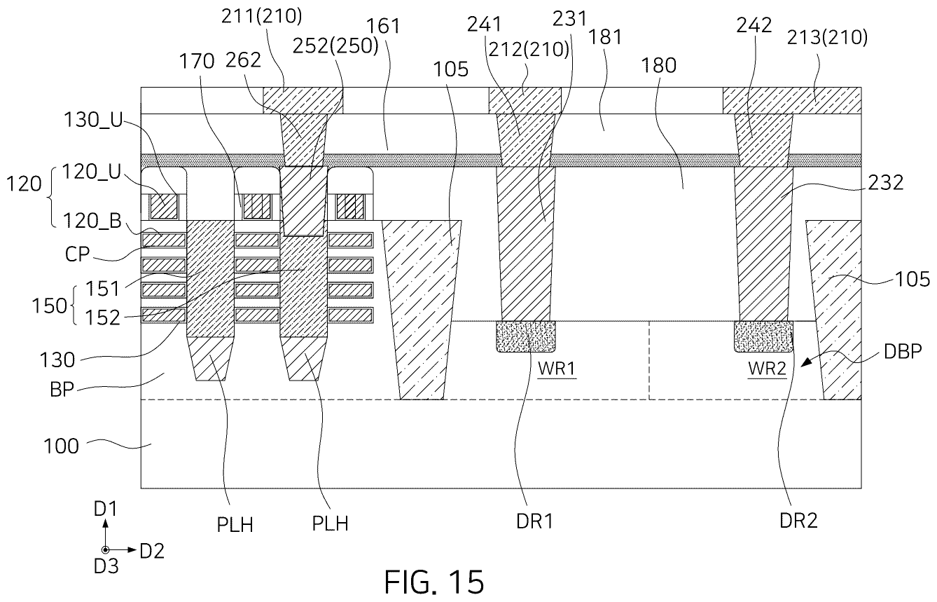

The lower blocking layer 111 may be formed in the second region. The lower blocking layer 111 may be formed on the doped bottom pattern DBP (shown in, for example, FIG. 15) so that the bottom pattern (shown in, for example, FIG. 15) is to be removed, and the doped bottom pattern DBP may not be to be removed. The lower blocking layer 111 may be formed on the doped bottom pattern DBP and a portion of the bottom surface of the device isolation layer 105. The lower blocking layer 111 may be configured of, for example, oxide, nitride, or the like.

The bottom pattern BP may be replaced with the lower insulating layer 110 in the first region. After the bottom pattern is removed, the lower insulating layer 110 may be formed. The bottom surface of the lower insulating layer 110 may be coplanar with the bottom surface of the lower blocking layer 111. For example, a planarization process may be performed on the lower insulating layer 110 and the lower blocking layer 111.

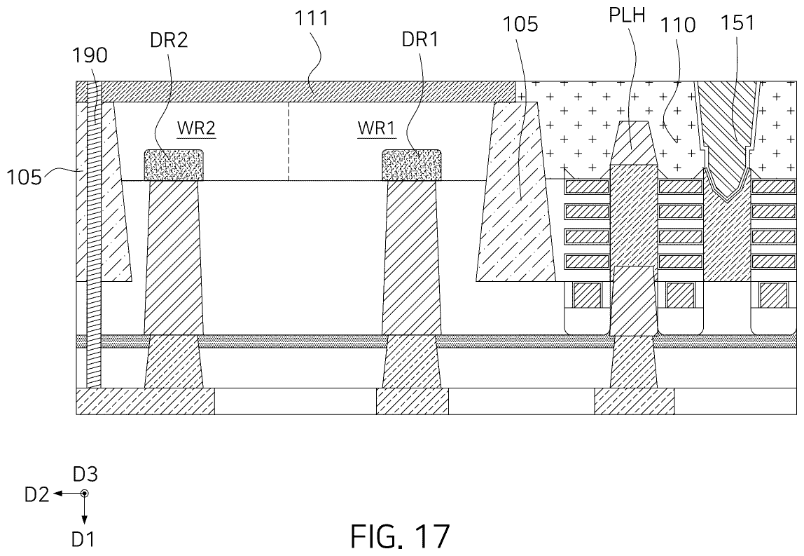

Referring to FIG. 17, the lower insulating layer 110, the sacrificial contact pattern PLH, and a portion of the first source/drain pattern 151 may be etched, and the lower source/drain contact 251 may be formed.

The lower blocking layer 111, the device isolation layer 105, the first interlayer insulating layer 180, the upper etch stop layer 161, and the second interlayer insulating layer 181 may be etched, and the conductive post 190 may be formed.

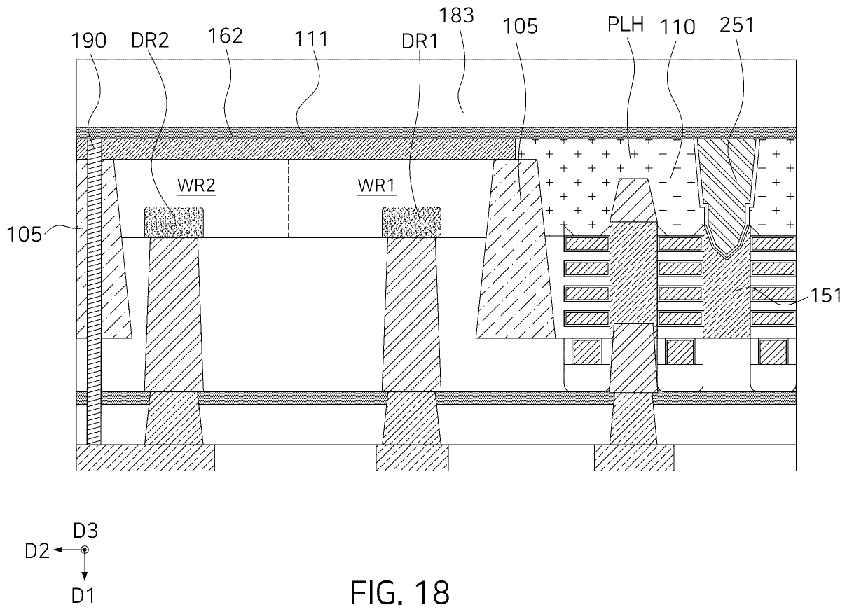

Referring to FIG. 18, the lower etch stop layer 162 may be formed on the lower insulating layer 110 and the lower blocking layer 111. The lower etch stop layer 162 may be disposed to prevent the device isolation layer 105 from being removed when a planarization process is performed on the lower insulating layer 110. For example, because the lower insulating layer 110 and the device isolation layer 105 are formed of the same oxide as each other, the lower etch stop layer 162 may prevent the device isolation layer 105 from being removed in the planarization process of the lower insulating layer.

The lower wire insulating layer 183 may be formed on the lower etch stop layer 162. The lower etch stop layer 162 may be disposed to cover a bottom surface of the conductive post 190 and the bottom surface of the lower source/drain contact 251. The lower etch stop layer 162 may be conformally formed.

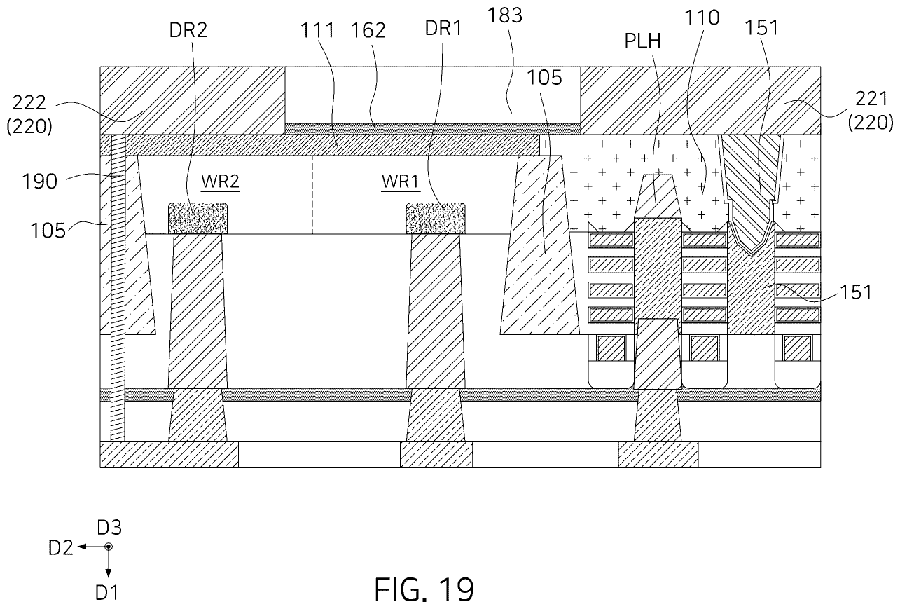

Referring to FIG. 19, the lower wire 220 may be formed in a lower side of the semiconductor device. A mask pattern may be formed on the lower wire insulating layer 183. The mask pattern may expose a portion of the lower wire insulating layer 183. For example, portions of the lower wire insulating layer 183 corresponding to the lower source/drain contact 251 and the conductive post 190, respectively, may be exposed.

An etch process may be performed on the lower wire insulating layer 183 and the lower etch stop layer 162 exposed through the mask pattern. Through the etch process, portions of the lower wire insulating layer 183 and the lower etch stop layer 162 may be removed. The lower wire 220 may be formed in the portions in which the lower wire insulating layer 183 and the lower etch stop layer 162 are removed. The first power line 221 may be in contact with the bottom surface of the lower source/drain contact 251, and the second power line 222 may be in contact with the bottom surface of the conductive post 190.

Hereinafter, the same reference numerals refer to the same elements of the semiconductor device of FIG. 1, and detailed description therefor will be omitted. For clarity, the description will be centered on different elements from those of the semiconductor device of FIG. 1.

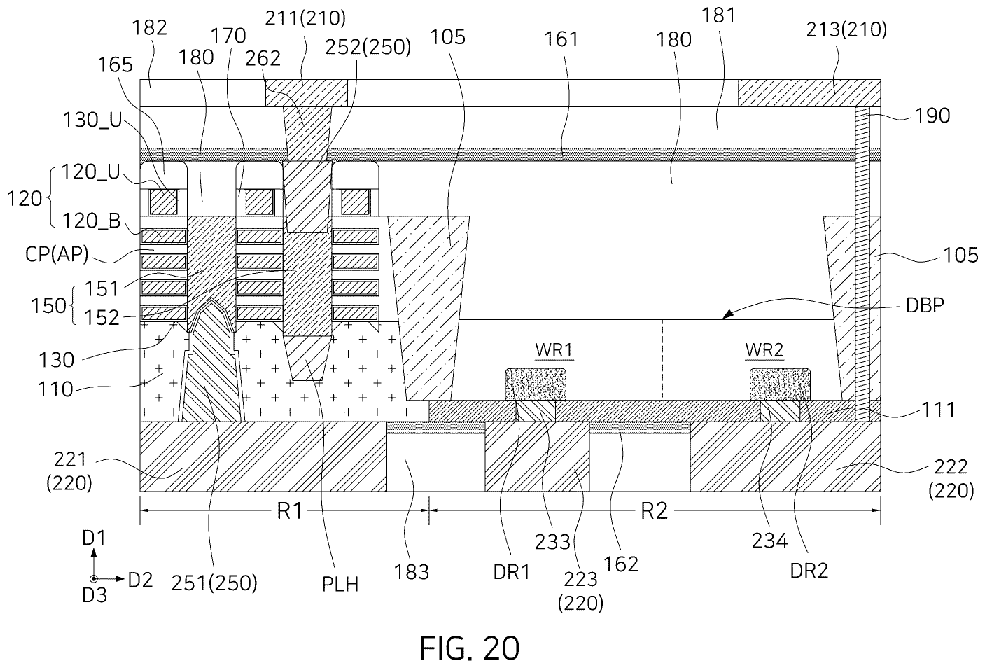

FIG. 20 is a cross-sectional view illustrating a semiconductor device according to some example embodiments of the present disclosure.

Referring to FIG. 20, the semiconductor device according to some example embodiments may include lower contacts 233 and 234.

A doped bottom pattern DBP may include a first well region WR1 and a second well region WR2. The first well WR1 and the second well region WR2 may be positioned at the same level as each other. The first well region WR1 and the second well region WR2 may be disposed side by side in a second direction D2. The first well region WR1 and the second well region WR2 may be disposed to overlap in the second direction D2.

In some example embodiments, a first doped region DR1 and a second doped region DR2 may be disposed in a lower side of the doped bottom pattern DBP. The first doped region DR1 may be disposed in a lower side of the first well region WR1, and the second doped region DR2 may be disposed in a lower side of the second well region WR2. A bottom surface of the first doped region DR1, a bottom surface of the second doped region DR2, a bottom surface of the first well region WR1, and a bottom surface of the second well region WR2 may be coplanar with each other. The first doped region DR1 and the second doped region DR2 may be formed through an ion implantation process after a substrate is removed.

The lower contacts 233 and 234 may be disposed within a lower blocking layer 111. The lower contacts 233 and 234 may pass through the lower blocking layer 111. Top surfaces of the lower contacts 233 and 234 may be in contact with the bottom surfaces of the first doped region DR1 and the second doped region DR2, respectively and bottom surfaces of the lower contacts 233 and 234 may be in contact with a lower wire 220. A silicide layer may be formed between a first lower contact 233 and the first doped region DR1. A silicide layer may be formed between a second lower contact 234 and the second doped region DR2.

The first lower contact 233 may be disposed on the bottom surface of the first doped region DR1 disposed in the lower side of the first well region WR1. The second lower contact 234 may be disposed on the bottom surface of the second doped region DR2 disposed in the lower side of the second well region WR2. A top surface of the first lower contact 233 may be in contact with the bottom surface of the first doped region DR1, and a top surface of the second lower contact 234 may be in contact with the bottom surface of the second doped region DR2.

The lower wire 220 may include a third power line 223 disposed on a bottom surface of the first lower contact 233. The third power line 223 may extend in a third direction D3. The third power line 223 may pass through a lower wire insulating layer 183 and a lower etch stop layer 162. The third power line 223 may supply power to the first doped region DR1 through the first lower contact 233. The first doped region DR1 may be electrically connected to the third power line 223 through the first lower contact 233. The second doped region DR2 may be electrically connected to a second power line 222 through the second lower contact 234.

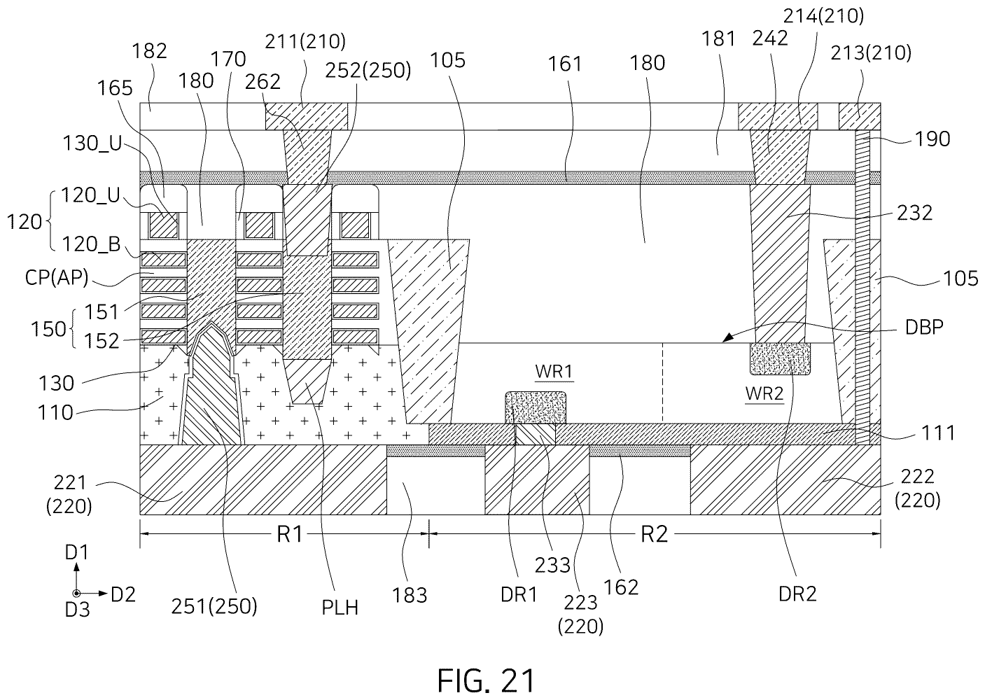

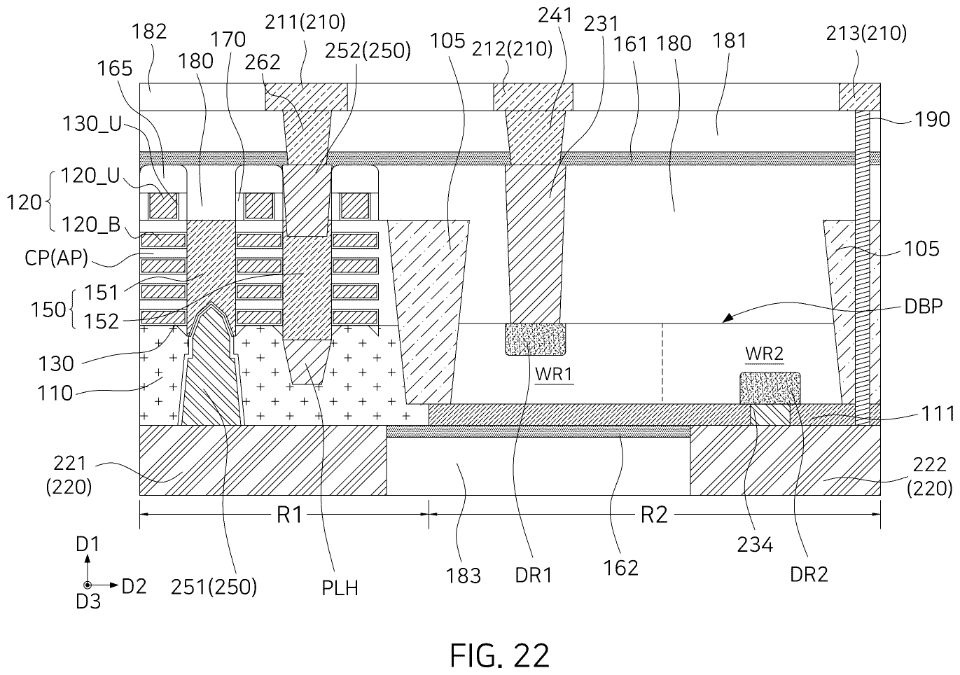

FIG. 21 is a cross-sectional view illustrating a semiconductor device according to some example embodiments of the present disclosure. FIG. 22 is a cross-sectional view illustrating a semiconductor device according to some example embodiments of the present disclosure.

Referring to FIGS. 21 and 22, the semiconductor devices according to some example embodiments may include an upper contact 231 or 232 disposed in any one of a first doped region DR1 and a second doped region DR2. The upper contact 231 and 232 may extend in a first direction D1.

A doped bottom pattern DBP may include a first well region WR1 and a second well region WR2. Referring to FIG. 21, the first doped region DR1 may be disposed in a lower side of the doped bottom pattern DBP, and the second doped region DR2 may be disposed in an upper side of the doped bottom pattern DBP. The first doped region DR1 may be disposed in a lower side of the first well region WR1, and the second doped region DR2 may be disposed in an upper side of the second well region WR2. The first doped region DR1 and the second doped region DR2 may be disposed in different levels from each other. The first doped region DR1 and the second doped region DR2 may be disposed to non-overlap in a second direction D2. However, example embodiments are not limited thereto, and the first doped region DR1 and the second doped region DR2 may be disposed to partially overlap in the second direction D2.

The upper contact 232 may be disposed on the second doped region DR2. The description for the upper contact 232 of FIG. 1 may be equally applied to the upper contact 232.

A lower contact 233 may be disposed within a lower blocking layer 111. The lower contact 233 may pass through the lower blocking layer 111. A top surface of the lower contact 233 may be in contact with a bottom surface of the first doped region DR1, and a bottom surface of the lower contact 233 may be in contact with a lower wire 220.

An upper wire 210 may include a third upper wire 213 electrically connected to the lower wire 220 through a conductive post 190, and a fourth upper wire 214 electrically connected to the upper contact 232. The third upper wire 213 and the fourth upper wire 214 may be spaced apart from each other in the second direction D2. However, example embodiments are not limited thereto, and the third upper wire 213 and the fourth upper wire 214 may be connected to each other.

The lower wire 220 may include a third power line 223 disposed on the bottom surface of the lower contact 233. The third power line 223 may extend in a third direction D3. The third power line 223 may pass through a lower wire insulating layer 183 and a lower etch stop layer 162. The third power line 223 may supply power to the first doped region DR1 through the lower contact 233.

Referring to FIG. 22, the first doped region DR1 may be disposed in an upper side of the doped bottom pattern DBP, and the second doped region DR2 may be disposed in a lower side of the doped bottom pattern DBP. The first doped region DR1 may be disposed in an upper side of the first well region WR1, and the second doped region DR2 may be disposed in a lower side of the second well region WR2.

The upper contact 231 may be disposed in the first doped region DR1. The description for the upper contact 231 of FIG. 1 may be equally applied to the upper contact 231.

A lower contact 234 may be disposed within a lower blocking layer 111. The lower contact 234 may pass through the lower blocking layer 111. A top surface of the lower contact 234 may be in contact with a bottom surface of the second doped region DR2, and a bottom surface of the lower contact 234 may be in contact with a second power line 222.

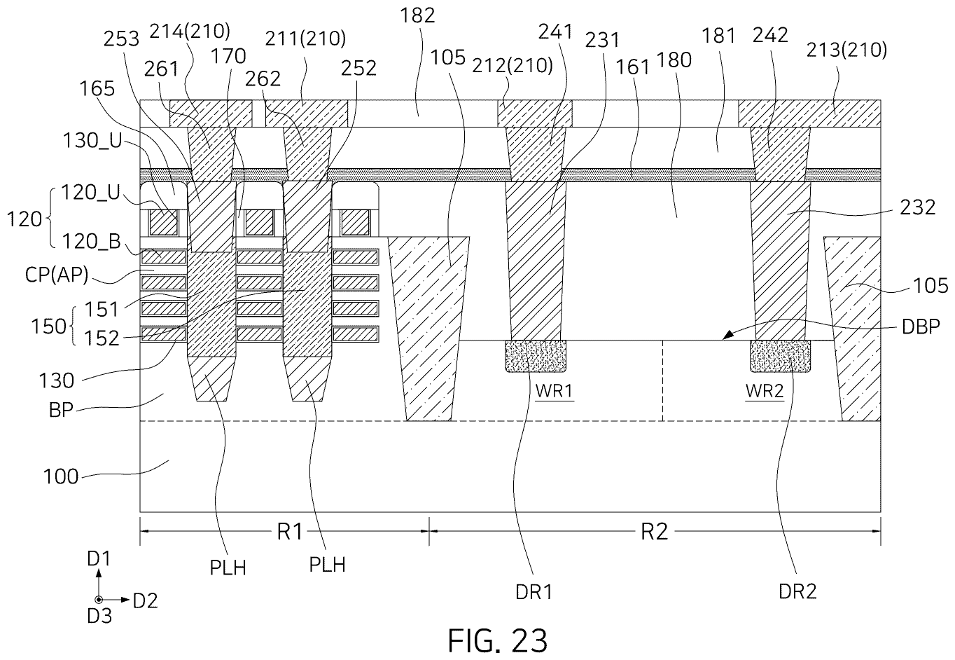

FIG. 23 is a cross-sectional view illustrating a semiconductor device according to some example embodiments of the present disclosure.

Referring to FIG. 23, the semiconductor device according to some example embodiments may include a first upper source/drain contact 253 disposed on a first source/drain pattern 151 and a second upper source/drain contact 252 disposed on a second source/drain pattern 152. The description for the upper source/drain contact 252 of FIG. 1 may be equally applied to the second upper source/drain contact 252.

The first upper source/drain contact 253 may be disposed in an upper side of the first source/drain pattern 151. The first upper source/drain contact 253 may pass through a first interlayer insulating layer 180 and a portion of the first source/drain pattern 151. The first upper source/drain contact 253 may electrically connect an upper wire 210 and the first source/drain pattern 151.

An upper via 261 may be disposed on the first upper source/drain contact 253. The upper via 261 may pass through an upper etch stop layer 161 and a second interlayer insulating layer 181. The upper via 261 may electrically connect the first source/drain pattern 151 and the upper wire 210.

The upper via 261 may be electrically connected to a fourth upper wire 214.

The fourth upper wire 214 may extend in a third direction D3. A top surface of the upper via 261 may be in contact with a bottom surface of the fourth upper wire 214, and a bottom surface of the upper via 261 may be in contact with a top surface of the first upper source/drain contact 253.

Referring to FIG. 23, the semiconductor device according to some example embodiments may include a protruding bottom pattern BP and a doped bottom pattern DBP on a substrate 100.

The bottom pattern BP may protrude from the substrate 100. The bottom pattern may extend in the third direction D3. The bottom pattern BP may be disposed to be spaced apart from the adjacent doped bottom pattern DBP in a second direction D2. The bottom pattern BP may be separated from the adjacent doped bottom pattern DBP by a device isolation layer 105. A plurality of channel patterns CP may be disposed on the bottom pattern BP. The respective channel patterns CP may be spaced apart from each other in the third direction D3.

The bottom pattern BP may be formed by etching a portion of the substrate 100, but example embodiments are not limited thereto. For example, the bottom pattern BP may include an epitaxial layer grown from the substrate 100. The bottom pattern BP may include Si or Ge as an elemental semiconductor material. The bottom pattern BP may be a region doped with an impurity like the doped bottom pattern DBP.

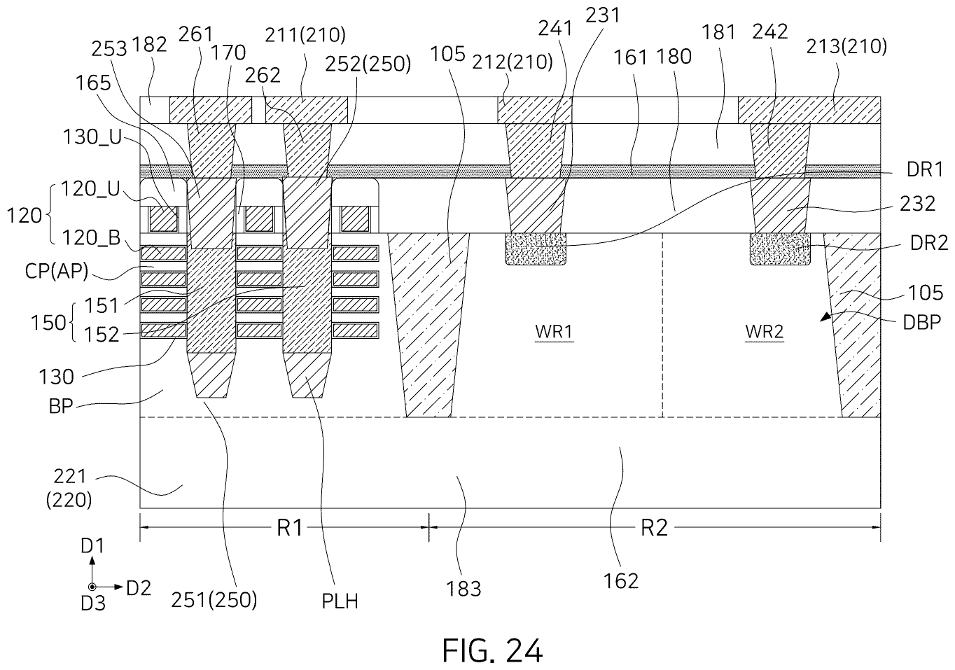

FIG. 24 is a cross-sectional view illustrating a semiconductor device according to some example embodiments of the present disclosure.

Referring to FIG. 24, a doped bottom pattern DBP may be disposed on the same level as channel patterns CP and lower gate electrodes 120_B of a first element in a second direction D2. The doped bottom pattern DBP may overlap the channel patterns CP and the lower gate electrodes 120_B of the first element in the second direction D2. A bottom surface of the doped bottom pattern DBP may be positioned on the same level as a bottom surface of a bottom pattern BP and a bottom surface of a device isolation layer 105.

A top surface of the doped bottom pattern DBP may be positioned on the same level as a top surface of the device isolation layer 105. The top surface of the doped bottom pattern DBP may be positioned on the same level as a top surface of an uppermost channel pattern CP or a top surface of an active pattern AP. However, example embodiments are not limited thereto, and the top surface of the doped bottom pattern DBP may be positioned at a level lower than the top surface of the device isolation layer 105.

In some example embodiments, the doped bottom pattern DBP may be formed by removing nanosheets and filling a silicon layer by a thickness corresponding to a removed thickness of the nanosheets. In other example embodiments, the doped bottom pattern DBP may be a region in which the nanosheets are not formed. In the other example embodiments, a stack structure on the doped bottom pattern DBP may not be formed, and thus a process of removing the stack structure may not be performed.

The doped bottom pattern DBP may include a first a well region WR1 and a second well region WR2. The first well region WR1 and the second well region WR2 may be positioned on the same level as each other. The first well region WR1 and the second well region WR2 may be disposed side by side in the second direction D2. The first well region WR1 and the second well region WR2 may be disposed to overlap in the second direction D2.

In some example embodiments, a first doped region DR1 and a second doped region DR2 may be disposed in an upper side of the doped bottom pattern DBP. The first doped region DR1 may be disposed in an upper side of the first well region WR1, and the second doped region DR2 may be disposed in an upper side of the second well region WR2.

Although not illustrated, like the above-described example embodiments, at least one of the first doped region DR1 and the second doped region DR2 may be disposed in a lower side of the doped bottom pattern DBP.

Certain examples of the present disclosure have been described above for purposes of illustration only, and those skilled in the art with ordinary knowledge of the present disclosure will be able to make various modifications, changes and additions within the spirit and scope of the present disclosure, and such modifications, changes and additions should be construed to be included in a scope of the claims.

1. A semiconductor device, comprising:
an active pattern comprising a plurality of channel patterns stacked to be spaced apart from each other in a first direction in a first region;
a gate electrode surrounding the plurality of channel patterns;
a doped bottom pattern comprising a first well region having a dopant concentration of a first conductivity type and a second well region at the same level as the first well region and having a dopant concentration of a second conductivity type in a second well region;
a device isolation layer between the active pattern and the doped bottom pattern in a second direction intersecting with the first direction;
a first doped region formed within the first well region and having a dopant concentration of the first conductivity type larger than the dopant concentration of the first conductivity type within the first well region; and
a second doped region formed within the second well region and having a dopant concentration of the second conductivity type larger than the dopant concentration of the second conductivity type within the second well region,
wherein a bottom surface of the device isolation layer is positioned at a level corresponding to a bottom surface of the doped bottom pattern, and
the first doped region and the second doped region are positioned at a level equal to or higher than the bottom surface of the device isolation layer.

2. The semiconductor device according to claim 1, further comprising an upper wire at a level higher than the active pattern and the doped bottom pattern,
wherein at least one of the first doped region and the second doped region is electrically connected to the upper wire.

3. The semiconductor device according to claim 2, further comprising a source/drain pattern at a side of the plurality of channel patterns,
wherein the source/drain pattern is electrically connected to the upper wire.

4. The semiconductor device according to claim 3, further comprising:
a lower insulating layer at a level lower than the channel patterns;
a lower blocking layer at a level lower than the doped bottom pattern; and
a lower wire at a level lower than the lower insulating layer and the lower blocking layer.

5. The semiconductor device according to claim 4, wherein
at least one of the first doped region and the second doped region is electrically connected to the lower wire.

6. The semiconductor device according to claim 4, further comprising a lower source/drain contact positioned on the source/drain pattern through the lower insulating layer, and electrically connecting the source/drain pattern and the lower wire.

7. The semiconductor device according to claim 4, further comprising a conductive post extending in the first direction and connecting between the upper wire and the lower wire.

8. The semiconductor device according to claim 3, wherein
the first doped region is positioned in an upper side of the first well region, and the second doped region is positioned in an upper side of the second well region, the semiconductor device further comprises:
an upper contact on at least one of the first doped region and the second doped region, and extending in the first direction; and
a first via which electrically connecting the upper contact and the upper wire.

9. The semiconductor device according to claim 8, further comprising:
an upper source/drain contact extending in the first direction on the source/drain pattern; and
a second upper via electrically connecting the source/drain pattern and the upper wire,
wherein a length of the upper contact is larger than that of the upper source/drain contact.

10. The semiconductor device according to claim 1, wherein the first doped region is positioned in a lower side of the first well region, and the second doped region is positioned in a lower side of the second well region,
the semiconductor device further comprises:
a first lower contact on the first doped region; and
a second lower contact on the second doped region.

11. The semiconductor device according to claim 10, further comprising:
a lower insulating layer at a level lower than the channel patterns;
a lower blocking layer at a level lower than the doped bottom pattern; and
a lower wire at a level lower than the lower insulating layer and the lower blocking layer,
wherein the first lower contact and the second lower contact pass through the lower blocking layer to be in contact with the lower wire, respectively.

12. The semiconductor device according to claim 1, wherein
the first doped region is positioned in an upper side of the first well region, and the second doped region is positioned in a lower side of the second well region,
the semiconductor device further comprises a lower contact on the second doped region.

13. The semiconductor device according to claim 1, further comprising a bottom pattern at a level lower than the active pattern, and on the same level as the doped bottom pattern,
wherein a bottom surface of the bottom pattern is positioned at the same level as the bottom surface of the device isolation layer.

14. The semiconductor device according to claim 1, wherein
an upper surface of the doped bottom pattern is positioned at a level corresponding to an upper surface of the active pattern.

15. A semiconductor device, comprising:
a lower insulating layer in a first region and a lower blocking layer in a second region;
an active pattern comprising a plurality of channel patterns stacked to be spaced apart from each other in a first direction on the lower insulating layer;
a gate electrode surrounding the plurality of channel patterns;
a source/drain pattern in one sides of the plurality of channel patterns;
a doped bottom pattern comprising a first well region and a second well region positioned side by side in a second direction intersecting with the first direction on the lower blocking layer;
a first doped region formed in the first well region; and
a second doped region formed in the second well region,
wherein a bottom surface of the lower blocking layer is coplanar with a bottom surface of the lower insulating layer.

16. The semiconductor device according to claim 15, further comprising:
a lower etch stop layer on the bottom surface of the lower insulating layer and the bottom surface of the lower blocking layer; and
a lower wire at a level lower than the lower insulating layer and the lower blocking layer, and positioned in one side of the lower etch stop layer.

17. The semiconductor device according to claim 16, further comprising a lower contact penetrating the lower blocking layer, the lower contact electrically connecting at least one of the first doped region and the second doped region and the lower wire.

18. The semiconductor device according to claim 15, further comprising:
an upper wire at a level higher than the active pattern and the doped bottom pattern; and
an upper contact extending in the first direction on at least one of the first doped region and the second doped region,
wherein a bottom surface of the upper contact is positioned at a level corresponding to a bottom surface of the gate electrode.

19. The semiconductor device according to claim 18, further comprising:
an upper source/drain contact extending in the first direction on the source/drain pattern, a top surface of the upper source/drain contact is coplanar with a top surface of the upper contact; and
an upper etch stop layer on the top surface of the upper source/drain contact and the top surface of the upper contact.

20. A semiconductor device, comprising:
a lower insulating layer in a first region, and a lower blocking layer in a second region;
an active pattern comprising a plurality of channel patterns stacked to be spaced apart from each other in a first direction on the lower insulating layer;
a gate electrode surrounding the plurality of channel patterns;
a source/drain pattern in one sides of the plurality of channel patterns;
a doped bottom pattern comprising a first well region and a second well region which overlap in a second direction intersecting with the first direction on the lower blocking layer;
a device isolation layer between the active pattern and the doped bottom pattern in the second direction;
a first doped region formed in an upper side of the first well region;
a second doped region formed in an upper side of the second well region, and positioned at a level corresponding to the first doped region;
a first upper contact extending in the first direction on the first doped region;
a second upper contact extending in the first direction on the second doped region;
an upper wire at a level higher than the active pattern and the doped bottom pattern, and a lower wire at a level lower than the lower insulating layer and the lower blocking layer,
a lower source/drain contact positioned on the source/drain pattern through the lower insulating layer, and electrically connecting the source/drain pattern and the lower wire; and
a conductive post extending in the first direction and connecting between the upper wire and the lower wire.
